(19) United States
(12) Patent Application Publication
(10) Pub. No.: US 2017/0121844 A1
(43) Pub. Date: May 4, 2017

(54) METHOD FOR MANUFACTURING SILICON CARBIDE SINGLE CRYSTAL AND SILICON CARBIDE SUBSTRATE

(71) Applicant: Sumitomo Electric Industries, Ltd., Osaka-shi, Osaka (JP)

(72) Inventor: Tomohiro KAWASE, Itami-shi, Hyogo (JP)

(73) Assignee: Sumitomo Electric Industries, Ltd., Osaka-shi, Osaka (JP)

(21) Appl. No.: 15/319,107

(22) PCT Filed: Jun. 24, 2015
(86) PCT No.: PCT/JP2015/068162

§ 371 Date: Dec. 15, 2016

(30) Foreign Application Priority Data
Jul. 7, 2014 (JP) 2014-139432

(51) Int. Cl. C30B 23/06; C30B 29/36

(52) U.S. Cl. CPC C30B 23/06; C30B 29/36

(57) ABSTRACT

A method for manufacturing a silicon carbide single crystal includes the steps of: preparing a supporting member having a bond portion and a stepped portion, the stepped portion being disposed at at least a portion of a circumferential edge of the bond portion; and disposing a buffer material on the stepped portion. The bond portion and the buffer material constitutes a supporting surface. Furthermore, this manufacturing method includes the steps of: disposing a seed crystal on the supporting surface and bonding the bond portion and the seed crystal to each other; and growing a single crystal on the seed crystal.

### TECHNICAL FIELD

The present disclosure relates to a method for manufacturing a silicon carbide single crystal and a silicon carbide substrate.

### BACKGROUND ART

Many silicon carbide substrates (wafers) are manufactured using a sublimation method (so-called “modified Lely method”) (for example, see Japanese Patent Laying-Open No. 2004-269297 (Patent Document 1) and Japanese Patent Laying-Open No. 2004-338971 (Patent Document 2)).

### CITATION LIST

### Patent Document

PTD 1: Japanese Patent Laying-Open No. 2004-269297

PTD 2: Japanese Patent Laying-Open No. 2004-338971

### SUMMARY OF INVENTION

A method for manufacturing a silicon carbide single crystal according to one embodiment of the present disclosure includes the steps of: preparing a supporting member having a bond portion and a stepped portion, the stepped portion being disposed at at least a portion of a circumferential edge of the bond portion; disposing a buffer material on the stepped portion, the bond portion and the buffer material constituting a supporting surface; disposing a seed crystal on the supporting surface and bonding the bond portion and the seed crystal to each other; and growing a single crystal on the seed crystal.

A silicon carbide substrate according to one embodiment of the present disclosure has a diameter of not less than 150 mm, and includes: a central region having a diameter of 50 mm; and an outer circumferential region formed along an outer circumferential end with a distance of not more than 10 mm from the outer circumferential end, if it is assumed that a reference orientation represents an average of crystal plane orientations measured at arbitrary three points in the central region, a deviation being not more than 200 arcsecs between the reference orientation and a crystal plane orientation measured at an arbitrary point in the outer circumferential region.

### BRIEF DESCRIPTION OF DRAWINGS

FIG. 1 is a flowchart schematically showing a method for manufacturing a silicon carbide single crystal according to one embodiment of the present disclosure.

FIG. 2 is a schematic cross sectional view illustrating a part of the method for manufacturing the silicon carbide single crystal according to one embodiment of the present disclosure.

FIG. 3 is a schematic plan view showing an exemplary supporting member according to one embodiment of the present disclosure.

FIG. 4 is a schematic plan view showing another exemplary supporting member according to one embodiment of the present disclosure.

FIG. 5 is a schematic cross sectional view showing an exemplary supporting member according to one embodiment of the present disclosure.

FIG. 6 is a schematic plan view showing an exemplary configuration of the silicon carbide substrate according to one embodiment of the present disclosure.

FIG. 7 is a schematic view illustrating an exemplary method for measuring a deviation in crystal plane orientation.

### DESCRIPTION OF EMBODIMENTS

### Description of Embodiment of the Present Disclosure

First, embodiments of the present disclosure are listed and described. In the description below, the same or corresponding elements are given the same reference characters and are not described repeatedly. Regarding crystallographic indications in the present specification, an individual orientation is represented by [ ], a group orientation is represented by < >, and an individual plane is represented by ( ), and a group plane is represented by { }. Generally, a crystallographically negative index is supposed to be indicated by putting “-” (bar) above a numeral, but is indicated by putting the negative sign before the numeral in the present specification.

A sublimation method is a crystal growth method in which a source material is sublimated under a high temperature and the sublimated source material is recrystallized on a seed crystal. Normally, in this method, the source material is accommodated in a lower portion of a growth container (for example, crucible composed of graphite), and the seed crystal is bonded and fixed to a supporting member (for example, a cover of the crucible) located at the upper portion of the growth container. With progress in such a sublimation method in recent years, a technique has begun to be established to mass-produce silicon carbide (SiC) substrates each having a diameter of about not more than 100 mm (for example, about 4 inches). For the real popularization of SiC power devices, however, it is necessary to mass-produce SiC substrates each having a larger diameter, i.e., a diameter of not less than 150 mm (for example, not less than 6 inches).

In order to provide a substrate having a larger diameter, it is essential to reduce crystal defects because crystal defects are increased as the diameter of the substrate becomes larger. Conventionally, various methods have been proposed to reduce crystal defects. For example, Patent Document 1 proposes to dispose a stress buffer material between the seed crystal and the mount (supporting member) in the sublimation method. Accordingly, thermal stress resulting from a difference in thermal expansion coefficient between the seed crystal and the mount is relaxed by the stress buffer material, thereby preventing strain in lattice plane and macroscopic defects in the grown SiC single crystal.

On the other hand, Patent Document 2 proposes to provide a buffer member between a seed crystal and a mount and couple the buffer member to the mount without using an adhesive agent. Accordingly, warpage of the buffer member resulting from a difference in thermal expansion coefficient between the seed crystal and the buffer member is tolerated, thereby preventing strain in the lattice plane of the grown crystal.

However, each of these methods is insufficient as a technique for mass-producing large-diameter substrates because the rate of crystal growth may be decreased. A graphite sheet used as the above-described stress buffer material or buffer member has a structure in which a plurality of graphite layers are stacked on one another. Such a graphite sheet exhibits a high thermal conductivity in an in-plane direction of the graphite layers (in-plane direction of the sheet), but exhibits a relatively low thermal conductivity in the stacking direction of the graphite layers (thickness direction of the sheet). For example, the thermal conductivity in the in-plane direction is about 134 W/(m·K) whereas the thermal conductivity in the stacking direction is only about 4.7 W/(m·K). Since the graphite sheet has such a low thermal conductivity in the thickness direction, a large temperature difference is caused in the thickness direction of the graphite sheet when the graphite sheet is provided between the seed crystal and the mount, with the result that a temperature difference between the grown crystal and the source material becomes small to decrease the rate of crystal growth.

In addition, the above-described method also lacks stability in production. Specifically, the seed crystal may be separated to fall off from the mount when the seed crystal bonded to the graphite sheet is fixed thereto. This is due to the following reason: in the graphite sheet, breaking strength between the graphite layers is low to readily result in breaking between the graphite layers when the mass of the grown crystal is increased or when thermal stress is caused due to a difference in thermal expansion coefficient between the seed crystal and the graphite sheet. If the seed crystal is partially separated but does not fall off from the mount, the seed crystal (SiC) is sublimated to the low temperature side (mount side) at the separated portion, with the result that fine through holes are formed in the grown crystal. Such a phenomenon is noticeable particularly when growing a large-diameter single crystal.

[1] A method for manufacturing a silicon carbide single crystal according to one embodiment of the present disclosure includes the steps of: preparing a supporting member having a bond portion and a stepped portion, the stepped portion being disposed at at least a portion of a circumferential edge of the bond portion; disposing a buffer material on the stepped portion, the bond portion and the buffer material constituting a supporting surface; disposing a seed crystal on the supporting surface and bonding the bond portion and the seed crystal to each other; and growing a single crystal on the seed crystal.

According to the description above, a SiC substrate having a large diameter (for example, a diameter of not less than 150 mm) can be manufactured. In the manufacturing method, first, a seed crystal is directly bonded to the supporting member at the bond portion. By bonding the seed crystal directly to the supporting member with no buffer material being interposed therebetween in this way, the seed crystal can be held stably without causing a problem such as falling. Further, since no buffer material is located at the bond portion, no large temperature difference is caused between the supporting member and the seed crystal, whereby a temperature difference between the source material and the grown crystal can be maintained. Accordingly, a rate of crystal growth suitable for mass production can be realized.

According to a research by the present inventor, when growing a SiC single crystal having a large diameter, thermal stress resulting from a difference in thermal expansion coefficient between the supporting member and the seed crystal is likely to be caused in the vicinity of the outer circumference of the SiC single crystal. In the manufacturing method, the stepped portion is provided at at least a portion of the circumferential edge of the bond portion (for example, the region of the supporting member corresponding to the outer circumference of the SiC single crystal), and the buffer material (for example, a graphite sheet) is disposed on the stepped portion. By doing so, the thermal stress caused in the vicinty of the outer circumference of the seed crystal can be relaxed efficiently. That is, crystal defects can be reduced in the outer circumference of the SiC single crystal. Here, it is assumed that the term “stepped portion” indicates a portion depressed to be lower than the bond portion (surface) (in a direction to separate away from the seed crystal).

[2] The supporting surface has a circular planar shape, and if it is assumed that the supporting surface has a diameter d₁, the stepped portion may be located outside a central region that includes a central point of the supporting surface and that has a diameter of not less than 0.5d₁.

By securing the bond portion having a diameter of not less than 0.5d₁, the seed crystal can be stably supported by the supporting member. Moreover, during the crystal growth, heat provided to the SiC single crystal and the seed crystal can be dissipated through the bond portion. According to the above configuration, the bond portion includes a portion corresponding to the vicinity of the center of each of the seed crystal and the SiC single crystal. Accordingly, in the SiC single crystal, a temperature distribution can be formed in which the temperature of the vicinity of the center is lower than that of its surroundings when viewed in a plan view. In this way, the rate of crystal growth is increased in the vicinity of the center as compared with that in its surroundings, whereby the SiC single crystal can be provided with a projecting outer shape, which is ideal in view of crystal quality. That is, according to the above configuration, crystal quality can be improved.

[3] In the step of disposing the buffer material, the buffer material may be disposed in axial symmetry to a center axis of the supporting member.

In order to manufacture a SiC single crystal having good crystal quality, it is desirable to form an axially symmetrical temperature distribution in the SiC single crystal. In that case, thermal stress applied to the SiC single crystal is also axially symmetrical, so that the thermal stress can be relaxed efficiently by disposing the buffer material in axial symmetry as described above.

[4] In the step of disposing the buffer material, the buffer material may be disposed in point symmetry to a central point of the supporting member.

According to such an embodiment, thermal stress can be relaxed efficiently when a temperature distribution is formed in point symmetry in the SiC single crystal.

[5] The supporting member includes a first supporting member having the bond portion, and a second supporting member joined to the first supporting member, and the supporting member can have the stepped portion at at least a portion of a circumferential edge of a portion at which the first supporting member and the second supporting member are joined to each other.

Thus, also according to the embodiment in which the supporting member is constituted of two components, crystal defects can be reduced in the outer circumference of the SiC single crystal while realizing the rate of crystal growth suitable for mass production as with [1] described above. Further, according to this embodiment, the first supporting member can be also composed of a material having a thermal expansion coefficient close to that of the seed crystal, whereby occurrence of the thermal stress can also be reduced.

[6] The buffer material may have a thickness of not less than 0.1 mm and not more than 2.0 mm. If the thickness is less than 0.1 mm, the effect of relaxing the thermal stress may be decreased. Further, since the thermal conductivity of the buffer material in the thickness direction is normally lower than the thermal conductivity of the supporting member in the perpendicular direction, a temperature difference becomes large at a portion of the buffer member having a thickness of more than 2 mm, thus presumably decreasing the effect of relaxing the thermal stress in the vicinity of the outer circumference in the SiC single crystal.

[7] The seed crystal may have a diameter of not less than 150 mm. Accordingly, a large-diameter substrate having a diameter of not less than 150 mm can be manufactured.

[8] A silicon carbide substrate according to one embodiment of the present disclosure has a diameter of not less than 150 mm, and includes: a central region having a diameter of 50 mm; and an outer circumferential region formed along an outer circumferential end with a distance of not more than 10 mm from the outer circumferential end, if it is assumed that a reference orientation represents an average of crystal plane orientations measured at arbitrary three points in the central region, a deviation being not more than 200 arcsecs between the reference orientation and a crystal plane orientation measured at an arbitrary point in the outer circumferential region.

Conventionally, large-diameter SiC substrates each having a diameter of not less than 150 mm have been suffering from a problem of frequent cracking of the substrates at outer circumferential regions during a device manufacturing process, and are therefore not in practical use. For example, a conventional large-diameter SiC substrate is readily cracked when provided with excessive force upon a conveyance process or when provided with an impact by hitting a portion of an apparatus.

When the present inventor manufactured a SiC substrate having a diameter of not less than 150 mm by using the above-mentioned manufacturing method, this SiC substrate was surprisingly very unlikely to be cracked in the device manufacturing process. As a result of fully analyzing a difference between a SiC substrate obtained using a conventional manufacturing method and the SiC substrate obtained using the manufacturing method according to one embodiment of the present disclosure, the present inventor found that the difference results from a deviation in crystal plane orientation at the outer circumferential region of the substrate.

Specifically, it was revealed that when it is assumed that a reference orientation represents an average of crystal plane orientations measured at arbitrary three points in the central region of the substrate, the substrate is not cracked when a deviation is not more than 200 arcsecs between the reference orientation and a crystal plane orientation measured at an arbitrary point in the outer circumferential region of the substrate, whereas the substrate is readily cracked when the deviation is more than 200 arcsecs. It can be said that such a correlation between the deviation (strain) in the crystal plane orientation and the cracking of the substrate is detected just because an un-cracked substrate is obtained by the manufacturing method according to one embodiment of the present disclosure. Specifically, in a cracked substrate, a crystal plane has been already released from constraints of surroundings, so that the deviation in crystal plane orientation cannot be detected in the first place.

Here, “arcsec” is a unit of angle, and indicates “1/3600°”. A crystal plane orientation can be measured by a double crystal X-ray diffraction method, for example. Further, the “arbitrary point in the outer circumferential region” desirably belong to a portion of the outer circumferential region having the largest lattice plane tilt as specified by, for example, X-ray topography.

[9] The silicon carbide substrate in [8] described above may have a thickness of not less than 0.3 mm and not more than 0.4 mm.

By setting the thickness of the substrate at not more than 0.4 mm, manufacturing cost of the device may be able to be reduced. On the other hand, by setting the thickness of the substrate at not less than 0.3 mm, handling in the device manufacturing process is facilitated. Generally, a thinner SiC substrate having a larger diameter is more likely to be cracked. Hence, conventionally, it has been very difficult to realize a substrate having a diameter of not less than 150 mm and a thickness of not more than 0.5 mm. However, when the deviation in crystal plane orientation is not more than 200 arcsecs as described in [8] above, even a substrate having a large diameter and a small thickness is not cracked in the device manufacturing process.

[10] In the silicon carbide substrate in [8] or [9], an absolute value of a difference may be not more than 20 arcsecs between (i) an average value of full width at half maximums of X-ray rocking curves of a (0004) plane measured at the arbitrary three points in the central region and (ii) a full width at half maximum of an X-ray rocking curve of the (0004) plane measured at the arbitrary point in the outer circumferential region.

### Details of Embodiment of the Present Disclosure

The following describes embodiments of the present disclosure in detail (hereinafter, also referred to as “the present embodiment”); however, the present embodiment should not be limited to these.

[Method for Manufacturing Silicon Carbide Single Crystal]

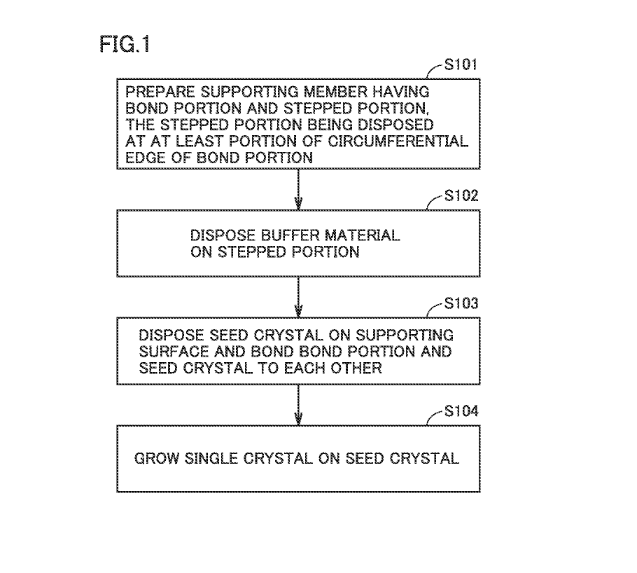

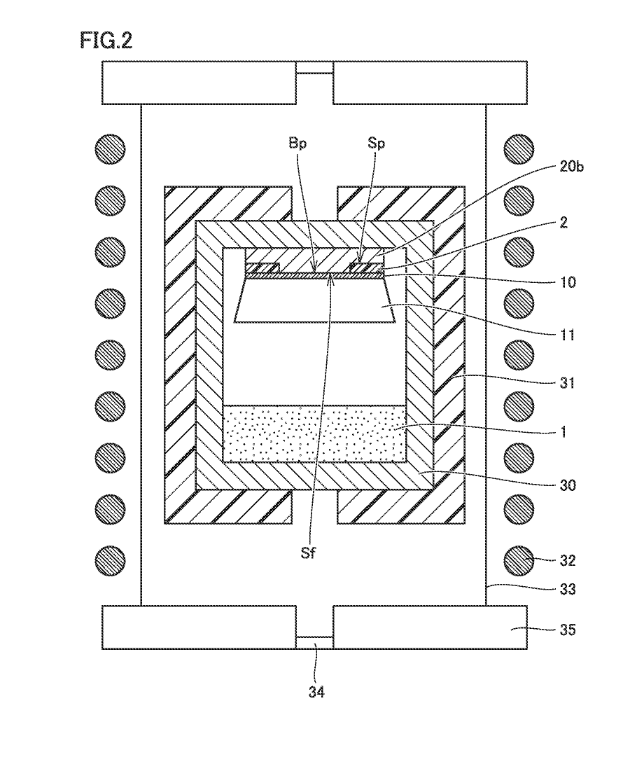

FIG. 1 is a flowchart schematically showing a manufacturing method in the present embodiment. FIG. 2 is a schematic cross sectional view illustrating a part of the manufacturing method. As shown in FIG. 1 and FIG. 2, the manufacturing method includes: a step (S101) of preparing a supporting member 20b having a bond portion Bp and a stepped portion Sp; a step (S102) of disposing a buffer material 2 on stepped portion Sp; a step (S103) of disposing a seed crystal 10 on a supporting surface Sf and bonding bond portion Bp and seed crystal 10 to each other; and a step (S104) of growing a single crystal 11 on seed crystal 10. Hereinafter, each of the steps will be described.

[Step (S101) of Preparing Supporting Member]

In this step, a supporting member is prepared which has a bond portion Bp and stepped portions Sp at at least a portion of the circumferential edge of bond portion Bp. The supporting member is composed of, for example, graphite and may serve as a cover of a crucible 30 (see FIG. 2).

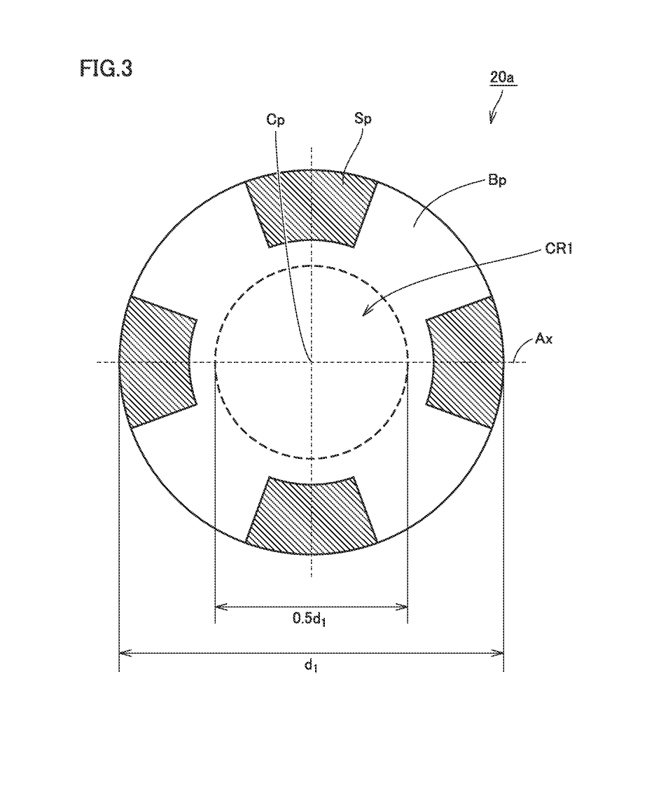

FIG. 3 is a schematic plan view showing an exemplary supporting member. As shown in FIG. 3, supporting member 20a has a circular planar shape, and has bond portion Bp and stepped portions Sp, which are depressed to be lower than bond portion Bp. As described below, a buffer material 2 is disposed at each of stepped portions Sp, whereby bond portion Bp and buffer material 2 constitute a supporting surface Sf (see FIG. 2). In FIG. 3, four stepped portions Sp are provided; however, the number of stepped portions Sp is not particularly limited as long as stepped portion(s) Sp are provided at at least a portion of supporting member 20a.

In FIG. 3, the diameter of supporting member 20a (i.e., diameter of supporting surface SI) is illustrated as d₁. As diameter d₁ is larger, a seed crystal having a large diameter can be supported more stably. The present embodiment is directed to manufacturing a single crystal having a large diameter (for example, a diameter of not less than 150 mm). Hence, diameter d₁ is preferably not less than 150 mm, is more preferably not less than 175 mm, and is particularly preferably not less than 200 mm. It should be noted that diameter d₁ may be not more than 300 mm.

On this occasion, it is preferable to provide each stepped portion Sp outside a central region CR1, which includes a central point Cp in a plan view of supporting member 20a and which has a diameter of not less than 0.5d₁. This is because thermal stress generated in the outer circumferential region of single crystal 11 can be relaxed while securing an area for bond portion Bp. The diameter of central region CR1 is more preferably not less than 0.6d₁, and is particularly preferably not less than 0.7d₁. This is because by increasing the area of bond portion Bp, heat is dissipated from the vicinity of the center of single crystal 11 to facilitate controlling the outer shape of single crystal 11 into a projecting shape. If the outer shape of single crystal 11 can be formed into a projecting shape at an initial stage of the growth, a different type of polytype can be more likely to be suppressed from being introduced therein.

In order to grow single crystal 11 into the projecting shape, it is desirable to form an axially symmetrical temperature distribution in single crystal 11. Hence, in accordance with this temperature distribution, stepped portions Sp are preferably provided in axial symmetry to center axis Ax of supporting member 20a such that buffer material 2 is disposed to face a portion in which thermal stress is likely to be generated due to the temperature distribution.

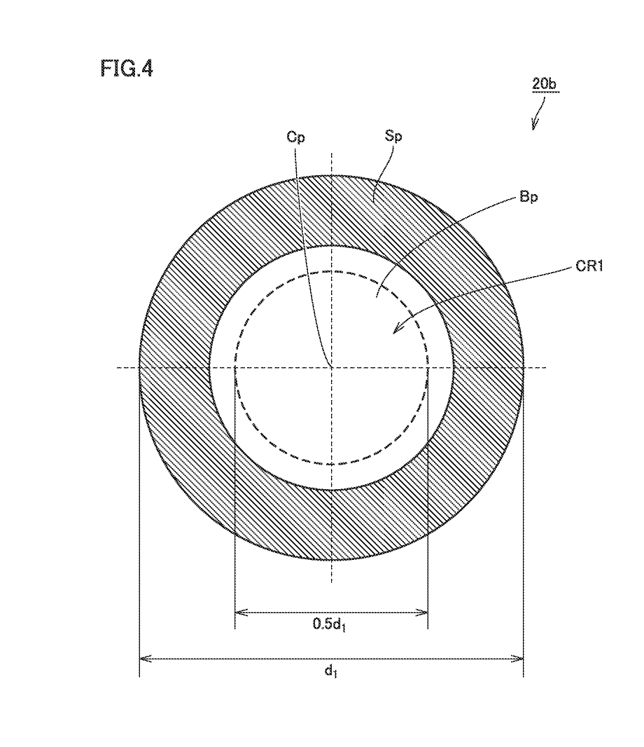

Further, the temperature distribution thus caused in single crystal 11 is more desirably concentric, i.e., in point symmetry to the central point of single crystal 11. FIG. 4 is a schematic plan view showing an exemplary supporting member suitable for such a case. In a supporting member 20b shown in FIG. 4, stepped portion Sp is provided in point symmetry to central point Cp of supporting member 20b so as to surround bond portion Bp. Supporting member 20b can deal with the concentric temperature distribution, thereby improving the crystal quality of single crystal 11.

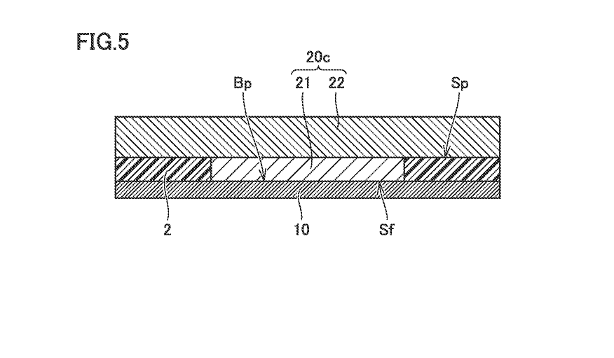

The supporting member may be constituted of two components, for example. FIG. 5 is a schematic cross sectional view showing an exemplary supporting member constituted of two components. A supporting member 20c includes a first supporting member 21 and a second supporting member 22. Second supporting member 22 is composed of graphite, for example. First supporting member 21, which has bond portion Bp, is desirably composed of a material having a thermal expansion coefficient close to that of seed crystal 10. For example, first supporting member 21 may be composed of a SiC single crystal or a SiC polycrystal. Of course, first supporting member 21 may be composed of graphite as with second supporting member 22.

First supporting member 21 and second supporting member 22 may be joined to each other by, for example, an adhesive agent, a fitting structure, or the like. Here, an exemplary suitable adhesive agent is a carbon adhesive agent. A carbon adhesive agent refers to an adhesive agent obtained by dispersing graphite grains in an organic solvent. A specific example thereof is “ST-201” provided by Nisshinbo Chemical,

Inc., or the like. Such a carbon adhesive agent can also be carbonized through heat treatment to firmly bond target objects to each other. For example, the carbon adhesive agent can be carbonized in the following manner: the carbon adhesive agent is temporarily held at a temperature of about not less than 150° C. and not more than 300° C. to vaporize the organic solvent, and is then held at a high temperature of about not less than 500° C. and not more than 1000° C.

[Step (S102) of Disposing Buffer Material]

In this step, buffer material 2 is disposed on stepped portion Sp. Buffer material 2 may be bonded to stepped portion Sp, or may be just placed thereon. By disposing buffer material 2 on stepped portion Sp as shown in FIG. 2, bond portion Bp and buffer material 2 constitute supporting surface Sf. As described above, buffer material 2 is preferably disposed in axial symmetry to center axis Ax of the supporting member, and is more preferably disposed in point symmetry to central point Cp of the supporting member.

(Buffer Material)

For buffer material 2, a material having heat resistance and good flexibility is suitable, such as a graphite sheet. Preferably, buffer material 2 has a thickness of not less than 0.1 mm and not more than 2.0 mm. If the thickness is less than 0.1 mm, an effect of relaxing thermal stress may be reduced. On the other hand, if the thickness is more than 2.0 mm, a temperature difference becomes large in the thickness direction of buffer material 2 to presumably result in reducing an effect of relaxing thermal stress in the vicinity of the outer circumference in the SiC single crystal. In order to relax the thermal stress efficiently, the thickness of buffer material 2 is more preferably not less than 0.1 mm and not more than 1.0 mm, and is particularly preferably not less than 0.2 mm and not more than 0.8 mm. When the buffer material is in the form of a sheet, a plurality of buffer materials may be stacked on one another and used. In such a case, it is assumed that the thickness of the buffer material refers to the total of the thicknesses of the plurality of buffer materials stacked on one another.

[Step (S103) of Bonding Bond Portion and Seed Crystal]

As shown in FIG. 2 or FIG. 5, in this step, bond portion Bp of the supporting member and seed crystal 10 are bonded to each other. For the bonding, the above-described carbon adhesive agent may be used, for example. Buffer material 2, which constitutes supporting surface Sf together with bond portion Bp, may not be bonded to seed crystal 10. However, it is desirable to form no space between buffer material 2 and seed crystal 10. This is due to the following reason: if there is a space therebetween, seed crystal 10 (SiC) is sublimated to the low-temperature side (supporting member side) in the space, with the result that fine through holes may be formed in seed crystal 10. For example, buffer material 2 and seed crystal 10 may be closely joined to each other so as not to form a space therebetween by using the adhesive agent in the same manner as that for bond portion Bp.

(Seed Crystal)

Seed crystal 10 may be prepared by slicing a SiC ingot (single crystal) of, for example, polytype 4H or 6H into a predetermined thickness. Polytype 4H is particularly beneficial for devices. For the slicing, a wire saw or the like may be used, for example. As shown in FIG. 2, a main surface (hereinafter, also referred as “growth surface”) of seed crystal 10 on which single crystal 11 is to be grown may correspond to a (0001) plane (so-called “Si plane”) or may correspond to a (000-1) plane (so-called “C plane”), for example.

The growth surface of seed crystal 10 may be desirably a surface obtained through slicing with a tilt of not less than 1° and not more than 10° relative to a {0001} plane. That is, the off angle of seed crystal 10 relative to the {0001} plane is desirably not less than 1° and not more than 10°. This is because crystal defects such as basal plane dislocation can be suppressed by limiting the off angle of seed crystal 10 in this way. The off angle is more preferably not less than 1° and not more than 8°, and is particularly preferably not less than 2° and not more than 8°. The off direction is a <11-20> direction, for example.

Seed crystal 10 has a circular planar shape, for example. As described above, the present embodiment is directed to suppressing crystal defects, which become noticeable when growing a SiC single crystal having a large diameter. Therefore, as a SiC single crystal having a larger diameter is grown using a seed crystal 10 having a larger diameter, the present embodiment is distinctively more superior to the conventional techniques. As described below, in an experiment employing a seed crystal having a diameter of 150 mm, the present inventor confirmed that the present embodiment is superior to the conventional techniques. If the diameter of the seed crystal is larger than 150 mm, it is expected that this distinction will be further increased. Hence, the diameter of seed crystal 10 is preferably not less than 150 mm, is more preferably not less than 175 mm (for example, not less than 7 inches), and is particularly preferably not less than 200 mm (for example, not less than 8 inches). It should be noted that the diameter of seed crystal 10 may be not more than 300 mm (for example, not more than 12 inches).

The thickness of seed crystal 10 may be not less than 0.5 mm and not more than 5 mm, for example. The present embodiment may be applied to a thin seed crystal having a thickness of not less than 0.5 mm and not more than 2 mm. This is because strain is more likely to be introduced as the seed crystal is thinner.

As shown in FIG. 2, a main surface (hereinafter, also referred to as “bond surface”) of seed crystal 10 to be bonded to bond portion Bp is preferably provided with a treatment for increasing surface roughness in order to increase strength of bonding with the supporting member (bond portion Bp). Examples of such a treatment include a polishing treatment employing abrasive grains having relatively large grain sizes. For example, the polishing may be performed using a diamond slurry with an average grain size of about not less than 5 μm and not more than 50 μm (preferably, not less than 10 μm and not more than 30 μm; more preferably, not less than 12 μm and not more than 25 μm). It is assumed that the “average grain size” herein refers to a median diameter (so-called “D50”) measured by a laser diffraction scattering method.

Alternatively, the bond surface may be an as-sliced surface, which has been formed by slicing and has not been polished. Such an as-sliced surface also has a large surface roughness and may be preferable in view of bonding strength.

[Step (S104) of Growing Single Crystal]

As shown in FIG. 2, in this step, single crystal 11 is grown on the growth surface of seed crystal 10. FIG. 2 shows an exemplary sublimation method. Although supporting member 20b is shown in FIG. 2, each of supporting member 20a and supporting member 20c described above can also be used.

First, source material 1 is contained in the bottom portion of crucible 30. For source material 1, a conventional SiC source material can be used. Examples thereof include powders obtained by pulverizing a SiC polycrystal or single crystal.

Next, supporting member 20b is disposed at the upper portion of crucible 30 such that the growth surface of seed crystal 10 faces source material 1. As described above, on this occasion, supporting member 20b may serve as a cover of crucible 30. A heat insulator 31 is disposed to surround crucible 30. These are disposed in a chamber 33 composed of quartz, for example. At the upper end portion and bottom end portion of chamber 33, flanges 35 composed of stainless steel are disposed and are provided with view ports 34. Through a view port 34, the temperature of the bottom portion or ceiling portion of crucible 30 can be measured and monitored by using a noncontact type thermometer such as a radiation thermometer (pyrometer), for example. Here, the temperature of the bottom portion reflects the temperature of source material 1, and the temperature of the ceiling portion reflects the temperature of each of seed crystal 10 and single crystal 11. A temperature environment in crucible 30 is controlled by an amount of current supplied to a high-frequency coil 32 disposed to surround chamber 33. The temperature of the bottom portion of crucible 30 is set at about not less than 2200° C. and not more than 2400° C., and the temperature of the ceiling portion of crucible 30 is set at about not less than 2000° C. and not more than 2200° C., for example. Accordingly, source material 1 is sublimated in the longitudinal direction of FIG. 2, whereby a sublimate is deposited on seed crystal 10 to grow into single crystal 11.

The crystal growth is performed in an Ar atmosphere by supplying argon (Ar) gas into chamber 33. If an appropriate amount of nitrogen (N₂) gas is supplied together with Ar on this occasion, the nitrogen serves as a dopant to provide n type conductivity type to single crystal 11. A pressure condition in chamber 33 is preferably not less than 0.1 kPa and not more than the atmospheric pressure, and is more preferably not more than 10 kPa in view of the rate of crystal growth.

As shown in FIG. 2, in the present embodiment, seed crystal 10 is directly bonded to supporting member 20b with no buffer material 2 interposed therebetween at bond portion Bp. This suppresses occurrence of a problem such as falling of seed crystal 10 during the crystal growth, and achieves a rate of crystal growth suitable for mass production.

On this occasion, thermal stress is generated at the outer circumference of seed crystal 10; however, buffer material 2 is disposed at the portion facing the outer circumference, thus relaxing the thermal stress. Hence, even a SiC single crystal having a large diameter of not less than 150 mm can be grown while maintaining crystal quality.

Heretofore, the present embodiment has been described while illustrating the sublimation method; however, the present embodiment should not be limited to the sublimation method and is widely applicable to single crystal manufacturing methods in which a single crystal is grown on a seed crystal fixed to the supporting member. For example, the present embodiment is applicable to a method for growing a single crystal from a vapor phase as with the sublimation method such as CVD (Chemical Vapor Deposition) employing various types of source material gases, and is also applicable to a method for growing a single crystal from a liquid phase such as flux method, liquid phase epitaxy, Bridgman method, or Czochralski method.

[Silicon Carbide Substrate]

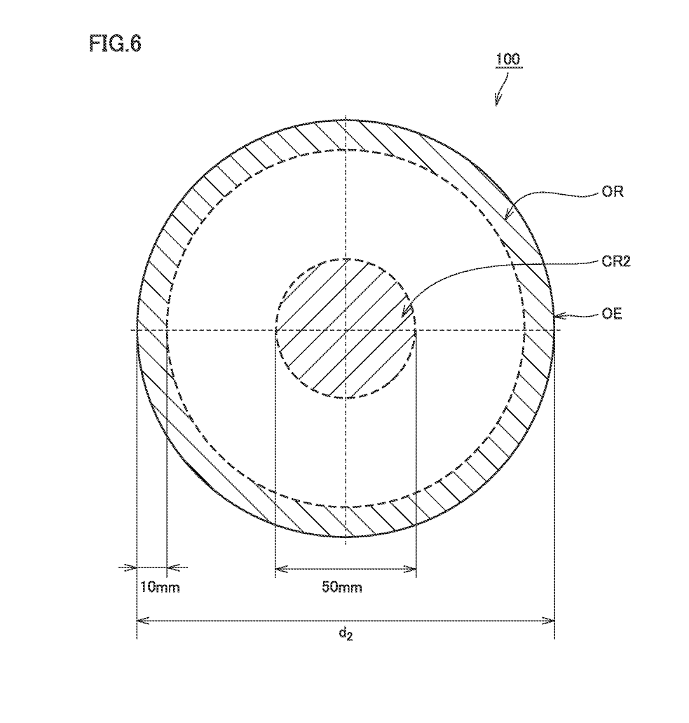

Next, the following describes a SiC substrate according to the present embodiment. FIG. 6 is a schematic plan view showing an overview of the SiC substrate according to the present embodiment. As shown in FIG. 6, SiC substrate 100 is a substrate having a diameter d₂ of not less than 150 mm, and includes: a central region CR2 having a diameter of 50 mm; and an outer circumferential region OR formed along an outer circumferential end OE with a distance of not more than 10 mm from outer circumferential end OE. SiC substrate 100 is typically obtained by slicing single crystal 11 (ingot) obtained through the above-described manufacturing method. Therefore, a deviation in crystal plane orientation is small between central region CR2 and outer circumferential region OR, whereby cracking takes place very unlikely in the device manufacturing process irrespective of the use of the substrate having a large diameter of not less than 150 mm.

The thickness of SiC substrate 100 is about not less than 0.1 mm and not more than 0.6 mm, for example. In view of material cost of devices, it is more preferable that SiC substrate 100 has a smaller thickness. However, as the SiC substrate is thinner, the SiC substrate is more likely to be cracked, thereby decreasing yield of devices to presumably increase the manufacturing cost of the devices. Particularly in the case of a substrate having a large diameter of not less than 150 mm, it is necessary to secure a certain thickness of the substrate in consideration of handling of the substrate. Hence, according to the conventional techniques, it has been very difficult to realize a SiC substrate having a diameter of not less than 150 mm and a thickness of not more than 0.5 mm.

In contrast, as shown in an evaluation described later, the SiC substrate in accordance with the present embodiment is not cracked in the device manufacturing process even when the SiC substrate has a thickness of not more than 0.4 mm. Hence, the thickness of SiC substrate 100 is preferably about not more than 0.5 mm, and is more preferably about not more than 0.4 mm. Accordingly, material cost of devices may be reduced. However, in consideration of handling of the substrate, the thickness of SiC substrate 100 is preferably about not less than 0.2 mm and is more preferably about not less than 0.3 μm. In other words, the thickness of SiC substrate 100 is preferably about not less than 0.2 mm and not more than 0.5 mm, and is most preferably about not less than 0.3 mm and not more than 0.4 mm. It should be noted that the diameter of the SiC substrate may be not more than 300 mm.

(Method for Measuring Deviation in Crystal Plane Orientation)

A deviation in crystal plane orientation between central region CR2 and outer circumferential region OR can be measured using a double crystal X-ray diffraction method, for example. However, this measuring method is just exemplary, and any method may be used as long as the deviation in crystal plane orientation can be measured using the method.

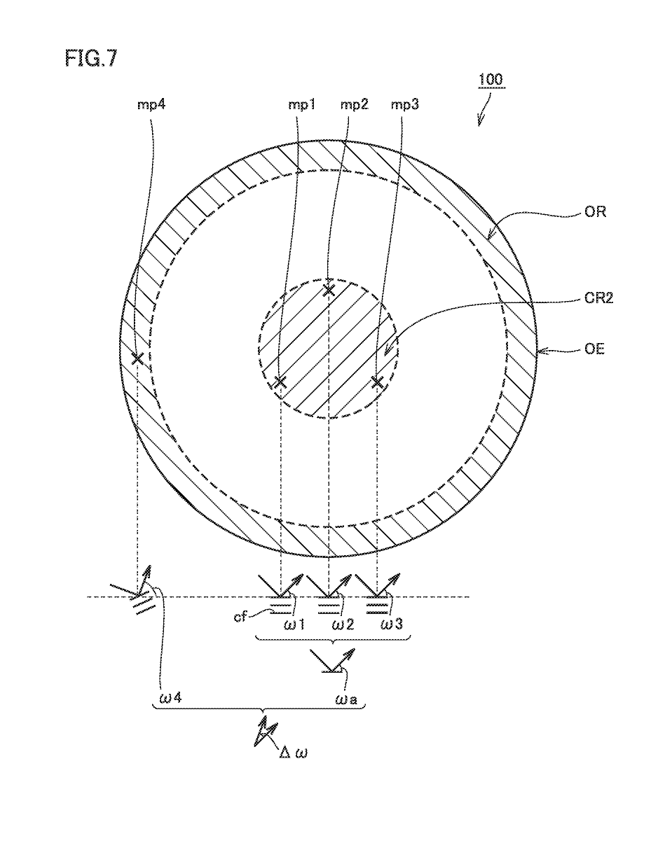

FIG. 7 is a schematic view illustrating an exemplary method for measuring a deviation in crystal plane orientation. Legends each in the form of “X” described in SiC substrate 100 represent measurement points for crystal plane orientation. A measurement point mp1, a measurement point mp2, and a measurement point mp3 belong to central region CR2, and a measurement point mp4 belongs to outer circumferential region OR. A crystal plane orientation in each measurement point is schematically shown in the lower portion of FIG. 7. Arrows in FIG. 7 represent incidence and reflection of X rays. A crystal plane cf is a {0001} plane, for example. In FIG. 7, for example, a crystal plane orientation in measurement point mp1 is represented as ω1 (°).

In the present embodiment, a reference orientation ωa is determined by averaging the crystal plane orientations in the three measurement points belonging to central region CR2. Reference orientation ωa can be calculated in accordance with the following formula (1):

ωa=(ω1+ω2+ω3)/3 Formula (1)

In doing so, three measurement points mp1, mp2, and mp3 can be freely selected; however, it is desirable to select them such that a distance among the measurement points is equal.

Next, a crystal plane orientation ω4 at measurement point mp4 belonging to outer circumferential region OR is measured. A deviation Δω between ω4 and ωa can be calculated in accordance with the following formula (2):

Δω=|ω4−ωa| Formula (2)

In the present embodiment, deviation Δω is not more than 200 arcsecs. In view of yield of devices, deviation Δω is more preferably not more than 100 arcsecs, and is particularly preferably not more than 50 arcsecs. A smaller deviation Δω is more desirable and deviation Δω is ideally 0°; however, the lower limit value of deviation Δω may be set at about 10 arcsecs in view of productivity.

The measurement above is performed in the following procedure, for example. First, X-ray topography is employed to specify a portion having the largest lattice plane tilt within outer circumferential region OR, measurement point mp4 is selected from that portion, and then double crystal X-ray diffraction method is employed to measure a lattice plane tilt (Δω).

Moreover, X-ray rocking curve (XRC) measurement may be performed at measurement point mp1, measurement point mp2, measurement point mp3, and measurement point mp4. It is assumed that a diffraction plane is a (0004) plane. At each measurement point, a full width at half maximum (FWHM) is measured. The measurement is performed under the following condition:

X-ray source: CuKα

Diffraction angle: 17.85°

Scanning rate: 0.1°/minute

Sampling interval: 0.002°.

The measurement is performed in a region of 1 mm×1 mm with each measurement point being the center thereof. The FWHMs at measurement point mp1, measurement point mp2, and measurement point mp3 are averaged, thus determining an average value of the FWHMs at the three points. An absolute value of a difference between the average value of the FWHMs and the FWHM of measurement point mp4 is determined. Hereinafter, the absolute value of the difference thus determined will be referred to as “ΔFWHM”. ΔFWHM also serves as an index of deviation between the crystal plane orientation in the central region and the crystal plane orientation in the outer circumferential region.

In the present embodiment, ΔFWHM is not more than 20 arcsecs. According to a research by the present inventor, a substrate having a ΔFWHM of more than 20 arcsecs is highly likely to be cracked during the device manufacturing process. On the other hand, a substrate having a ΔFWHM of not more than 20 arcsecs has high resistance against cracking. A smaller ΔFWHM is more desirable, and ΔFWHM is ideally 0 arcsec. The upper limit of ΔFWHM may be 19 arcsecs, may be 18 arcsecs, may be 17 arcsecs, or may be 16 arcsecs. The lower limit of ΔFWHM may be 0 arcsec, may be 5 arcsecs, may be 10 arcsecs, or may be 15 arcsecs.

[Evaluation]

SiC substrates were manufactured under manufacturing conditions α, β, and γ as described below, and evaluations were made with regard to a deviation in crystal plane orientation and handling in the device manufacturing process (whether or not it could withstand the manufacturing process without being cracked). In the following description, a substrate obtained under manufacturing condition α will be denoted as “substrate α1”, for example.

[Manufacturing Condition α]

[Step (S101) of Preparing Supporting Member]

As shown in FIG. 2 and FIG. 4, a supporting member 20b composed of graphite and having a circular planar shape was prepared. Here, supporting member 20b had a diameter d₁ of 150 mm, and a stepped portion Sp was formed outside a central region CR1 (bond portion Bp) including a central point Cp and having a diameter of 75 mm. Stepped portion Sp was formed to be depressed to be lower than bond portion Bp by 1.05 mm.

[Step (S102) of Disposing Buffer Material]

As shown in FIG. 2 and FIG. 4, a buffer material 2 (graphite sheet having a thickness of 1.0 mm) was disposed on stepped portion Sp, and buffer material 2 and supporting member 20b were bonded to each other using a carbon adhesive agent. Accordingly, a supporting surface Sf constituted of bond portion Bp and buffer material 2 was formed.

[Step (S103) of Bonding Bond Portion and Seed Crystal]

A SiC seed crystal 10 (having a diameter of 150 mm and a thickness of 1.5 mm) was prepared. Seed crystal 10 had a crystal structure of polytype 4H, and had a growth surface angled off by 4° relative to a (0001) plane. The above-described carbon adhesive agent is applied to the bond surface (surface opposite to the growth surface) of seed crystal 10, and is adhered to supporting surface Sf. Next, supporting member 20b thus having seed crystal 10 adhered thereon was held for 5 hours in a constant temperature oven set at 200° C. to vaporize an organic solvent included in the carbon adhesive agent. Then, supporting member 20b having seed crystal 10 adhered thereon was heated using a high-temperature furnace at 750° C. for 10 hours to carbonize the carbon adhesive agent. Accordingly, bond portion Bp, buffer material 2, and seed crystal 10 are bonded to one another.

[Step (S104) of Growing Single Crystal]

As shown in FIG. 2, a source material 1, which was SiC powder, was accommodated at the bottom portion of crucible 30 composed of graphite, and supporting member 20b having seed crystal 10 adhered thereon was disposed at the ceiling portion of crucible 30. Next, heat insulator 31 was disposed to surround crucible 30, and they were installed in a chamber 33 composed of quartz within a high-frequency type heater.

Chamber 33 was evacuated and then Ar gas was supplied to adjust a pressure in chamber 33 to 1.0 kPa. Further, the temperature of the bottom portion of crucible 30 was increased to 2300° C. and the temperature of the ceiling portion of crucible 30 was increased to 2100° C. while using a pyrometer (not shown) to monitor the temperatures of the bottom portion and ceiling portion of crucible 30 from two view ports 34 provided in the upper and lower portions of chamber 33. SiC single crystal 11 was grown for 50 hours under these pressure condition and temperature condition. In this way, single crystal 11 was obtained which had a maximum diameter of 165 mm and a height of 15 mm.

[Production of Substrate]

The side surface of single crystal 11 was ground, and then single crystal 11 was sliced by a wire saw into ten substrates. Further, the sliced surfaces of the substrates were mirror-polished, thereby obtaining substrates α1 to α10, which were mirror wafers having a thickness of 350 μm and a diameter of 150 mm.

[Measurement of Deviation in Crystal Plane Orientation]

A deviation Δω in crystal plane orientation of each of substrates α1 to α10 was measured in accordance with the above-described method. The result is shown in Table 1. As shown in Table 1, Δω in each of substrates α1 to α10 was not more than 200 arcsecs.

[Measurement of ΔFWHM]

In each of substrates α1 to α10, ΔFWHM was measured in accordance with the above-described method. The result is shown in Table 1. As shown in Table 1, ΔFWHM in each of substrates α1 to α10 was not more than 20 arcsecs.

TABLE 1

| | Deviation in Crystal | Half Width | |
|---|---|---|---|
| | Plane Orientation | Difference | |
| | Δω | ΔFWHM | Handling in Device |
| Substrate | arcsec | arcsec | Manufacturing Process |
| α1 | 200 | 19 | A |
| α2 | 198 | 19 | A |
| α3 | 197 | 18 | A |
| α4 | 196 | 17 | A |
| α5 | 195 | 17 | A |
| α6 | 194 | 17 | A |
| α7 | 193 | 16 | A |
| α8 | 192 | 16 | A |
| α9 | 191 | 15 | A |
| α10 | 190 | 15 | A |

[Production of Device]

Substrates α1 to α10 were used to produce MOSFETs (Metal Oxide Semiconductor Field Effect Transistor), and handling thereof in the device manufacturing process was evaluated with the following two criteria: “A” and “B”. The result is shown in Table 1. As shown in Table 1, no crack was generated in each of substrates α1 to α10 and handling thereof was good.

A: no crack was generated in the substrate.

B: a crack was generated in the substrate.

[Manufacturing Condition β]

In manufacturing condition β, a supporting member having no stepped portion was used as in the conventional techniques. The carbon adhesive agent was applied to the bond surface of seed crystal 10 and the whole surface of the bond surface was adhered to this supporting member. Under the same condition as manufacturing condition α apart from this, single crystal 11 was grown and substrates β1 to β10 were obtained.

A deviation Δω in crystal plane orientation of each of substrates β1 to β10 was measured in accordance with the above-described method. The result is shown in Table 2. As shown in Table 2, in each of substrates β1 to β10, a deviation in crystal plane orientation was about 220 to 250 arcsecs between the central region and the outer circumferential region.

Further, in each of substrates β1 to β10, ΔFWHM was measured in accordance with the above-described method. The result is shown in Table 2. As shown in Table 2, in each of substrates β1 to β10, ΔFWHM was more than 20 arcsecs.

TABLE 2

| | Deviation in Crystal | Half Width | |
|---|---|---|---|
| | Plane Orientation | Difference | |
| | Δω | ΔFWHM | Handling in Device |
| Substrate | arcsec | arcsec | Manufacturing Process |
| β1 | 250 | 30 | B |
| β2 | 243 | 29 | B |
| β3 | 237 | 29 | B |
| β4 | 232 | 28 | B |
| β5 | 228 | 26 | B |
| β6 | 225 | 25 | B |
| β7 | 223 | 24 | B |
| β8 | 222 | 24 | B |
| β9 | 221 | 23 | B |
| β10 | 220 | 22 | B |

Substrates β1 to β10 were used to produce MOSFETs, and evaluation was made with regard to handling thereof in the device manufacturing process in accordance with the above-described two criteria. The result is shown in Table 2. As shown in Table 2, all of substrates β1 to β10 were cracked during the manufacturing process, thus posing a difficulty in production of devices.

[Manufacturing Condition γ]

In manufacturing condition γ, the above-described graphite sheet was adhered to the whole surface of the bond surface of seed crystal 10 using the carbon adhesive agent, and then seed crystal 10 and supporting member 20b were bonded to each other with this graphite sheet interposed therebetween. Apart from these, single crystal 11 was grown under the same condition as manufacturing condition α.

As a result, in manufacturing condition γ, a portion of seed crystal 10 was separated from supporting member 20b during the crystal growth, which led to generation of a multiplicity of fine through holes in single crystal 11. Accordingly, no substrate usable for production of devices could be obtained.

It can be said that the following matters were proved from the above-described experimental results.

First, the method for manufacturing the SiC single crystal is suitable for mass production of large-diameter substrates, the method including: the step (S101) of preparing supporting member 20b having bond portion Bp and stepped portion Sp, the stepped portion Sp being disposed at at least a portion of the circumferential edge of bond portion Bp; the step (S102) of disposing buffer material 2 on stepped portion Sp, bond portion Bp and buffer material 2 constituting supporting surface Sf; the step (S103) of disposing seed crystal 10 on supporting surface Sf and bonding bond portion Bp to seed crystal 10; and the step (S104) of growing single crystal 11 on seed crystal 10.

Second, the SiC substrate is highly unlikely to be cracked in the device manufacturing process and can be practically used, the SiC substrate having a diameter d₂ of not less than 150 mm, the SiC substrate including: central region CR2 having a diameter of 50 mm; and outer circumferential region OR formed along outer circumferential end OE with a distance of not more than 10 mm from outer circumferential end OE, wherein if it is assumed that reference orientation ωa represents an average of crystal plane orientations measured at arbitrary three points in central region CR2, a deviation between reference orientation ωa and a crystal plane orientation measured at a point in outer circumferential region OR is not more than 200 arcsecs.

The embodiments disclosed herein are illustrative and non-restrictive in any respect. The scope of the present invention is defined by the terms of the claims, rather than the embodiments described above, and is intended to include any modifications within the scope and meaning equivalent to the terms of the claims.

### REFERENCE SIGNS LIST

1: source material; 2: buffer material; 10: seed crystal; 11: single crystal; 20a, 20b, 20c: supporting member; 21: first supporting member; 22: second supporting member; 30: crucible; 31: heat insulator; 32: high-frequency coil; 33: chamber; 34: view port; 35: flange; 100: substrate; Bp: bond portion; Sp: stepped portion; Sf: supporting surface; Cp: central point; CR1, CR2: central region; OR: outer circumferential region; OE: outer circumferential end; d₁, d₂: diameter; mp1, mp2, mp3, mp4: measurement point; cf: crystal plane; ω1, ω2, ω3, ω4: crystal plane orientation; ωa: reference orientation; Δω: deviation.

1. A method for manufacturing a silicon carbide single crystal, the method comprising the steps of:
preparing a supporting member having a bond portion and a stepped portion, the stepped portion being disposed at at least a portion of a circumferential edge of the bond portion;
disposing a buffer material on the stepped portion, the bond portion and the buffer material constituting a supporting surface;
disposing a seed crystal on the supporting surface and bonding the bond portion and the seed crystal to each other; and
growing a single crystal on the seed crystal.

2. The method for manufacturing the silicon carbide single crystal according to claim 1, wherein
the supporting surface has a circular planar shape, and
if it is assumed that the supporting surface has a diameter d₁, the stepped portion is located outside a central region that includes a central point of the supporting surface and that has a diameter of not less than 0.5d₁.

3. The method for manufacturing the silicon carbide single crystal according to claim 1, wherein in the step of disposing the buffer material, the buffer material is disposed in axial symmetry to a center axis of the supporting member.

4. The method for manufacturing the silicon carbide single crystal according to claim 1, wherein in the step of disposing the buffer material, the buffer material is disposed in point symmetry to a central point of the supporting member.

5. The method for manufacturing the silicon carbide single crystal according to claim 1, wherein
the supporting member includes a first supporting member having the bond portion, and a second supporting member joined to the first supporting member, and
the supporting member has the stepped portion at at least a portion of a circumferential edge of a portion at which the first supporting member and the second supporting member are joined to each other.

6. The method for manufacturing the silicon carbide single crystal according to claim 1, wherein the buffer material has a thickness of not less than 0.1 mm and not more than 2.0 mm.

7. The method for manufacturing the silicon carbide single crystal according to claim 1, wherein the seed crystal has a diameter of not less than 150 mm.

8. A silicon carbide substrate having a diameter of not less than 150 mm, the silicon carbide substrate comprising:
a central region having a diameter of 50 mm; and
an outer circumferential region formed along an outer circumferential end with a distance of not more than 10 mm from the outer circumferential end,
if it is assumed that a reference orientation represents an average of crystal plane orientations measured at arbitrary three points in the central region, a deviation being not more than 200 arcsecs between the reference orientation and a crystal plane orientation measured at an arbitrary point in the outer circumferential region.

9. The silicon carbide substrate according to claim 8, wherein the silicon carbide substrate has a thickness of not less than 0.3 mm and not more than 0.4 mm.

10. The silicon carbide substrate according to claim 9, wherein an absolute value of a difference is not more than 20 arcsecs between (i) an average value of full width at half maximums of X-ray rocking curves of a (0004) plane measured at the arbitrary three points in the central region and (ii) a full width at half maximum of an X-ray rocking curve of the (0004) plane measured at the arbitrary point in the outer circumferential region.

11. A silicon carbide substrate having a diameter of not less than 150 mm, the silicon carbide substrate comprising:
a central region having a diameter of 50 mm; and
an outer circumferential region formed along an outer circumferential end with a distance of not more than 10 mm from the outer circumferential end,
if it is assumed that a reference orientation represents an average of crystal plane orientations measured at arbitrary three points in the central region, a deviation being not more than 200 arcsecs between the reference orientation and a crystal plane orientation measured at an arbitrary point in the outer circumferential region, wherein
an absolute value of a difference is not more than 20 arcsecs between (i) an average value of full width at half maximums of X-ray rocking curves of a (0004) plane measured at the arbitrary three points in the central region and (ii) a full width at half maximum of an X-ray rocking curve of the (0004) plane measured at the arbitrary point in the outer circumferential region.

12. The method for manufacturing the silicon carbide single crystal according to claim 2, wherein
the supporting member includes a first supporting member having the bond portion, and a second supporting member joined to the first supporting member, and
the supporting member has the stepped portion at at least a portion of a circumferential edge of a portion at which the first supporting member and the second supporting member are joined to each other.

13. The method for manufacturing the silicon carbide single crystal according to claim 3, wherein
the supporting member includes a first supporting member having the bond portion, and a second supporting member joined to the first supporting member, and
the supporting member has the stepped portion at at least a portion of a circumferential edge of a portion at which the first supporting member and the second supporting member are joined to each other.

14. The method for manufacturing the silicon carbide single crystal according to claim 4, wherein
the supporting member includes a first supporting member having the bond portion, and a second supporting member joined to the first supporting member, and
the supporting member has the stepped portion at at least a portion of a circumferential edge of a portion at which the first supporting member and the second supporting member are joined to each other.

15. The method for manufacturing the silicon carbide single crystal according to claim 2, wherein the buffer material has a thickness of not less than 0.1 mm and not more than 2.0 mm.

16. The method for manufacturing the silicon carbide single crystal according to claim 3, wherein the buffer material has a thickness of not less than 0.1 mm and not more than 2.0 mm.

17. The method for manufacturing the silicon carbide single crystal according to claim 4, wherein the buffer material has a thickness of not less than 0.1 mm and not more than 2.0 mm.

18. The method for manufacturing the silicon carbide single crystal according to claim 5, wherein the buffer material has a thickness of not less than 0.1 mm and not more than 2.0 mm.
